(19) United States
(12) Patent Application Publication
(10) Pub. No.: US 2009/0323265 A1
(43) Pub. Date: Dec. 31, 2009

(54) CASING ASSEMBLY STRUCTURE

(76) Inventor: Kwok-Yan Leung, Willowdale (CA)

Correspondence Address: Muncy, Geissler, Olds & Lowe, PLLC, P.O. BOX 1364, FAIRFAX, VA, 22038-1364, US

(21) Appl. No.: 12/163,130

(22) Filed: Jun. 27, 2008

(51) Int. Cl. H05K 5/00; A47B 81/00

(52) U.S. Cl. 361/679.02; 312/223.2

(57) ABSTRACT

A casing assembly structure is provided. The casing assembly structure includes two side plates, a top plate, and a bottom plate. Top sides and bottom sides of the two side plates are configured with a plurality of slotted holes, respectively. Each of the slotted holes corresponds to a tenon configured at a sidewall of the side plates. The top plate is configured with projection ears downwardly extending from two sides of the top plate and corresponding to the slotted holes configured at the top sides of the two side plates. The bottom plate is configured with projection ears upwardly extending from two sides of the bottom plate and corresponding to the slotted holes configured at the bottom sides of the two side plates. Each of the projection ears is configured with a mortise adapted for engaging with the tenons. The projection ears of the top plate and the bottom plate are inserted into the slotted holes configured at the top sides and the bottom sides of the two side plates, respectively, so that the tenons and the mortises are engaged so as to complete the assembling of the casing.

### BACKGROUND OF THE INVENTION

1. Field of the Invention

The present invention relates generally to a casing for accommodating and protecting a storage medium, and more particularly, to a casing assembly structure being adapted for fast assembling.

2. The Prior Arts

Almost all current storage media such as removable hard drives, removable CD drives, are assembled in casings and thus equipped to computer hosts. Such a casing for storage media is typically produced by assembling a plurality of parts obtained by stamping and punching from metal plates, with screws.

However, such a casing is relatively complex for assembling, and thus being high in production cost.

### SUMMARY OF THE INVENTION

A primary objective of the present invention is to provide casing assembly structure having a simplified structure and adapted for fast and conveniently assembling.

The present invention is featured that the casing is assembled by interlocking a plurality of parts. The casing is constituted by a plurality of plate members. The plate members are assembled one to another by jointing of tenons and mortises. When disassembling the casing, the jointing can be conveniently disjointed by pressing and driving the tenons to disengage from the mortises.

After being completely assembled, the casing can be assembled with a front plate and a rear plate at a front end and a rear end thereof, respectively, and can be further accommodated in a housing, and equipped inside a computer host.

According to an embodiment of the present invention, the casing assembly structure includes two side plates, a top plate, and a bottom plate. Top sides and bottom sides of the two side plates are configured with a plurality of slotted holes, respectively. Each of the slotted holes corresponds to a tenon configured at a sidewall of the side plates. The top plate is configured with projection ears downwardly extending from two sides of the top plate and corresponding to the slotted holes configured at the top sides of the two side plates. The bottom plate is configured with projection ears upwardly extending from two sides of the bottom plate and corresponding to the slotted holes configured at the bottom sides of the two side plates. Each of the projection ears is configured with a mortise adapted for engaging with the tenons. The projection ears of the top plate and the bottom plate are inserted into the slotted holes configured at the top sides and the bottom sides of the two side plates, respectively, so that the tenons and the mortises are engaged so as to complete the assembling of the casing.

Comparing with the conventional casing, the present invention has a simplified structure, and can be fast and conveniently assembled with a lower production cost.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a perspective view of an assembled casing equipped with a storage medium according to an embodiment of the present invention;

FIG. 2 shows the casing of FIG. 1 without the storage medium;

FIG. 3 is an exploded perspective view of the casing illustrating the assembly relationship of main parts of the casing;

FIG. 4 is a side view of the casing illustrating an engagement between the top plate, the bottom plate, and the side plates;

FIG. 5 is a cross-sectional view of a side plate of the casing according to an embodiment of the present invention; and

FIG. 6 is a perspective view showing that the casing is accommodated in a housing according to an embodiment of the present invention.

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

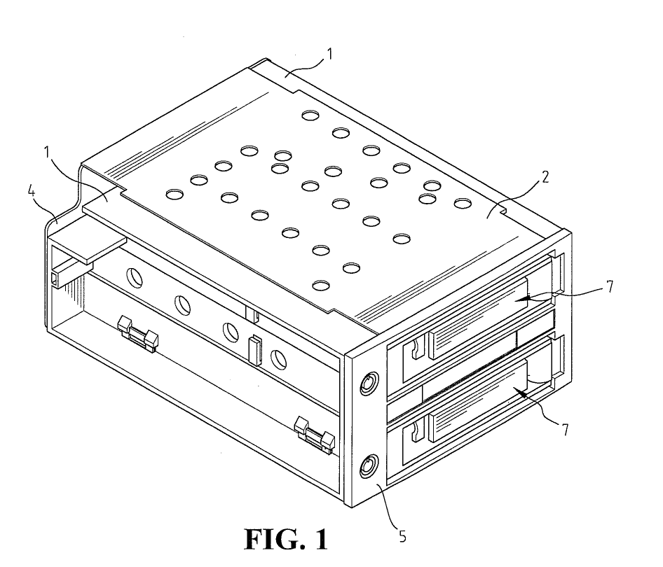

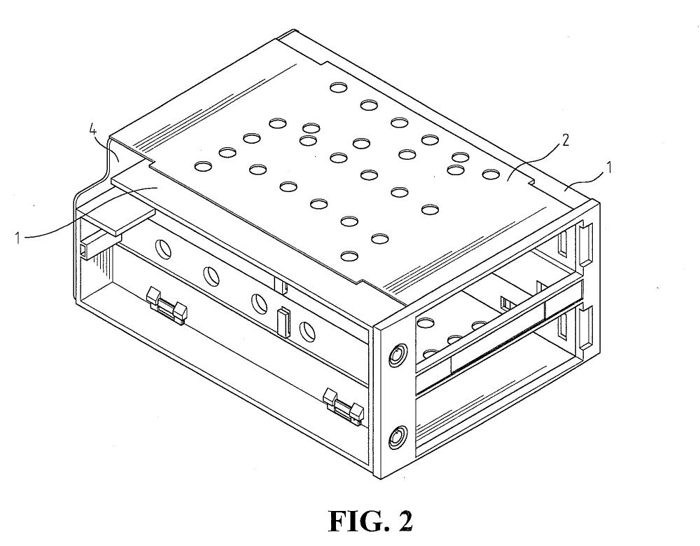

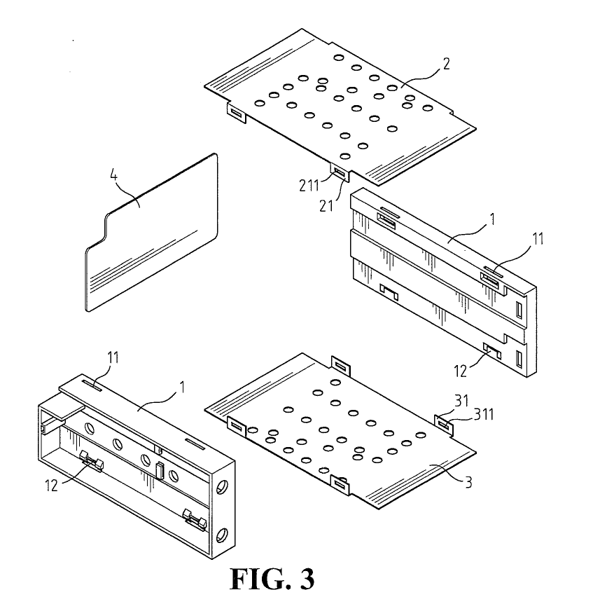

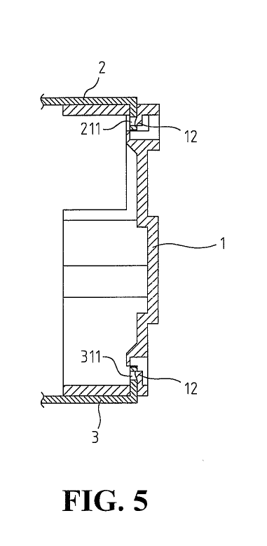

FIG. 1 is a perspective view of an assembled casing equipped with a storage medium according to an embodiment of the present invention. FIG. 2 shows the casing of FIG. 1 without the storage medium. FIG. 3 is an exploded perspective view of the casing illustrating the assembly relationship of main parts of the casing. Referring to FIGS. 1 through 3, the casing according to the present invention includes two side plates 1, a top plate 2, a bottom plate 3, a rear plate 4, and a front plate 5. Top sides and bottom sides of the two side plates 1 are configured with a plurality of slotted holes 11, respectively. Each of the slotted holes 11 corresponds to a tenon 12 configured at a sidewall of the side plates 1. The tenon 12 is integrally formed together with the side plate 1, so that the tenon 12 has one end connected to the side plate 1, and another end of the tenon 12 is a free end extending toward the corresponding slotted hole 11 as shown in FIG. 5.

The top plate 2 and the bottom plate 3 are structurally equivalent while disposed at opposite positions. The top plate 2 is configured with projection ears 21 downwardly extending from two sides of the top plate 2 and corresponding to the slotted holes 11 configured at the top sides of the two side plates 1. Each of the projection ears 21 is configured with a mortise 211 adapted for engagement with the tenon 12.

The bottom plate 3 is configured with projection ears 31 upwardly extending from two sides of the bottom plate 3 and corresponding to the slotted holes 11 configured at the bottom sides of the two side plates 1. Each of the projection ears 31 is configured with a mortise 311 adapted for engaging with the tenon 12.

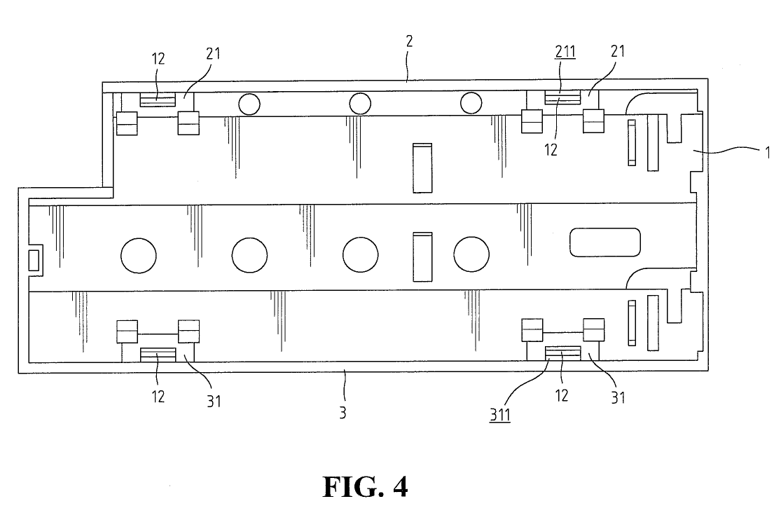

In assembling the casing, the projection ears 21 of the top plate 2 and the projection ears 31 of the bottom plate 3 are respectively inserted into the slotted holes 11 of the top sides and the bottom sides of the two side plates 1, so as to engage the tenons 12 of the tops sides and the bottom sides of the two side plates 1 with the mortises 211 of the top plate 2 and the mortises 311 of the bottom plate, as shown in FIG. 4.

In order to assemble a storage medium 7 such as a removable hard drive or a removable CD drive, after assembling the two side plates 1, the top plate 2, and the bottom plate 3 into a rectangular shaped casing, the casing can be provided with a front plate 5 at a front side of the casing and a rear plate 4 at a rear side of the casing. The rear plate 4 for example is a circuit board required by the storage medium, and is electrically connected with the storage medium 7.

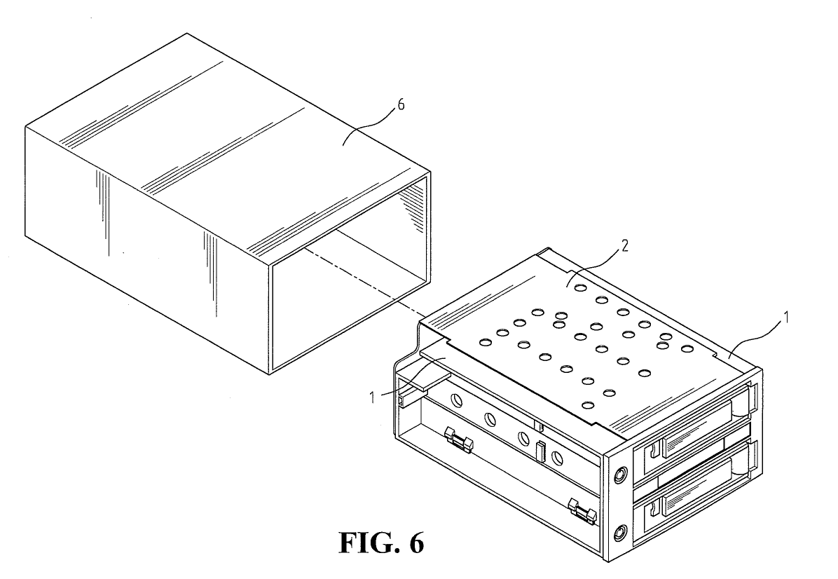

Therefore, the casing, together with the front plate 5, and the rear plate 4 can be accommodated in a housing 6, as shown in FIG. 6, for protecting the casing, as well as the storage medium 7.

Although the present invention has been described with reference to the preferred embodiments thereof, it is apparent to those skilled in the art that a variety of modifications and changes may be made without departing from the scope of the present invention which is intended to be defined by the appended claims.

1. A casing assembly structure, comprising:
two side plates, each of the two side plates comprising a plurality of slotted holes configured at a top side and a bottom side thereof, each of the slotted holes corresponding to a tenon configured at a sidewall of the side plates;
a top plate, configured with projection ears downwardly extending from two sides of the top plate, wherein each of the projection ears is configured with a mortise adapted for engagement with the tenons; and
a bottom plate, configured with projection ears upwardly extending from two sides of the bottom plate, wherein each of the projection ears is configured with a mortise adapted for engagement with the tenons,
wherein the projection ears of the top plate and the bottom plate are inserted into the slotted holes configured at the top sides and the bottom sides of the two side plates, respectively, so that the tenons and the mortises are engaged for firmly assembling a casing.

2. The casing assembly structure according to claim 1, further comprising:
a rear plate disposed at a rear side of the casing; and
a front plate disposed at a front side of the casing.
